(19) United States
(12) Patent Application Publication
(10) Pub. No.: US 2011/0079784 A1
(43) Pub. Date: Apr. 7, 2011

(54) THIN FILM TRANSISTOR, METHOD OF MANUFACTURING THE THIN FILM TRANSISTOR AND ORGANIC LIGHT EMITTING DISPLAY DEVICE HAVING THIN FILM TRANSISTOR

(75) Inventor: Ki-Ju Im, Yongin-city (KR)

(73) Assignee: Samsung Mobile Display Co., Ltd., Yongin-city (KR)

(21) Appl. No.: 12/892,855

(22) Filed: Sep. 28, 2010

(30) Foreign Application Priority Data
Oct. 6, 2009 (KR) 10-2009-0094561

(51) Int. Cl. H01L 51/50; H01L 29/12; H01L 21/84

(52) U.S. Cl. 257/59; 257/43; 438/157; 257/E29.068; 257/E21.703; 257/E51.018

(57) ABSTRACT

Embodiments relate to a thin film transistor using an oxide semiconductor as an active layer, a method of manufacturing the thin film transistor, and an organic light emitting display device having the thin film transistor. In one embodiment, the thin film transistor includes a substrate, a first gate electrode formed over the substrate, a gate insulating layer formed over the first gate electrode and substrate and an active layer, comprising an oxide semiconductor, formed on the gate insulating layer. The transistor further includes a passivation layer formed on the active layer, source and drain electrodes formed on the passivation layer and electrically connected to the active layer and a second gate electrode formed on the passivation layer and located between the source electrode and the drain electrode.

### CROSS-REFERENCE TO RELATED APPLICATIONS

This application claims priority to and the benefit of Korean Patent Application No. 10-2009-0094561, filed on Oct. 6, 2009, in the Korean Intellectual Property Office, the entire content of which is incorporated herein by reference.

This application relates to U.S. patent application entitled “Thin film transistor, method of manufacturing the thin film transistor and organic light emitting display device having thin film transistor” (Attorney docket: SMDSHN.152AUS), which is concurrently filed as this application and incorporated herein by reference in its entirety.

### BACKGROUND

1. Field of the Invention

Embodiments relate to a thin film transistor using an oxide semiconductor as an active layer, a method of manufacturing the thin film transistor, and an organic light emitting display device having the thin film transistor. More particularly, embodiments relate to a thin film transistor having a dual gate structure, a method of manufacturing the thin film transistor, and an organic light emitting display device having the thin film transistor.

2. Discussion of the Related Technology

In general, a thin film transistor includes an active layer providing a channel region, a source region, and a drain region and a gate electrode that is superimposed on the channel region and is insulated from the active layer by a gate insulating layer.

SUMMARY OF CERTAIN INVENTIVE ASPECTS

An embodiment provides a thin film transistor of which electrical characteristics can be improved, a method of manufacturing the thin film transistor, and an organic light emitting display device having the thin film transistor.

Another embodiment provides a thin film transistor capable of reducing the number of masks used in a manufacturing process, a method of manufacturing the thin film transistor, and an organic light emitting display device having the thin film transistor.

According to an aspect of the present invention, a thin film transistor includes: a substrate; a first gate electrode formed on the substrate; a gate insulating layer formed on the top including the first gate electrode; an active layer made of an oxide semiconductor on the gate insulating layer including the first gate electrode; a passivation layer formed on the active layer; source and drain electrodes formed on the passivation layer to connect the active layer; and a second gate electrode formed on the passivation layer between the source electrode and the drain electrode.

According to another aspect of the present invention, a method of manufacturing a thin film transistor includes: forming a first gate electrode on a substrate; forming a gate insulating layer on the top including the first gate electrode; forming an active layer made of an oxide semiconductor on the gate insulating layer including the first gate electrode; forming a passivation layer on the active layer; and forming source and drain electrodes connected to the active layer and a second gate electrode disposed between the source and drain electrodes on the passivation layer.

According to yet another aspect of the present invention, An organic light emitting display device includes: a first substrate including an organic light emitting element constituted by a first electrode, an organic light emitting layer, and a second electrode and a first substrate a thin film transistor for controlling an operation of the organic light emitting element; and a second substrate disposed to face the first substrate, wherein the thin film transistor includes: a first gate electrode formed on the first substrate; a gate insulating layer formed on the top including the first gate electrode; an active layer made of an oxide semiconductor on the gate insulating layer including the first gate electrode; a passivation layer formed on the active layer; source and drain electrodes formed on the passivation layer to connect the active layer; and a second gate electrode formed on the passivation layer between the source and drain electrodes.

According to an embodiment of the present invention, a thin film transistor has a dual gate structure. Since channels are formed on both surfaces of an active layer by bias voltage applied to two gate electrodes disposed at both sides of the active layer, current characteristics are improved in comparison with the known thin film transistor and it is possible to easily control threshold voltage V_{TH} to a desired level by controlling the magnitude of the bias voltage. Accordingly, the thin film transistor of the present invention has improved electrical characteristics.

Another aspect is a thin film transistor, comprising: a substrate; a first gate electrode formed over the substrate; a gate insulating layer formed over the first gate electrode and substrate; an active layer, comprising an oxide semiconductor, formed on the gate insulating layer; a passivation layer formed on the active layer; source and drain electrodes formed on the passivation layer and electrically connected to the active layer; and a second gate electrode formed on the passivation layer and located between the source electrode and the drain electrode.

In the above transistor, the passivation layer is formed on the active layer, and wherein the source and drain electrodes are electrically connected to the active layer through a contact hole formed on the passivation layer. In the above transistor, the second gate electrode at least partially overlaps with the first gate electrode. In the above transistor, the second gate electrode is spaced apart from the source electrode and the drain electrode. In the above transistor, the source electrode, the drain electrode, and the second gate electrode are made of the same material, and are formed on the same plane. In the above transistor, the oxide semiconductor contains zinc oxide (ZnO). In the above transistor, the oxide semiconductor comprises at least one ion of: gallium (Ga), indium (In), stanium (Sn), zirconium (Zr), hafnium (Hf), and vanadium (V). The above transistor further comprises a buffer layer formed between the substrate and the first gate electrode.

Another aspect is a method of manufacturing a thin film transistor, comprising: forming a first gate electrode over a substrate; forming a gate insulating layer on the first gate electrode; forming an semiconductor active layer on the gate insulating layer; forming a passivation layer on the active layer and gate insulating layer; and forming source and drain electrodes, and a second gate electrode on the passivation layer, wherein the source and drain electrodes are electrically connected to the active layer, and wherein the second gate electrode is disposed between the source and drain electrodes.

In the above method, forming a passivation layer comprises: forming the passivation layer on the active layer; and forming a contact hole on the passivation layer. In the above method, forming the source electrode, the drain electrode, and the second gate electrode comprises: forming a conductive layer on the passivation layer so as to fill the contact hole; and forming i) the source and drain electrodes so as to be electrically connected to the active layer through the contact hole and ii) the second gate electrode between the source and drain electrodes by patterning the conductive layer.

The above method further comprises using the passivation layer as an etch stop layer for patterning the conductive layer. In the above method, the second gate electrode at least partially overlaps with the first gate electrode. In the above method, the second gate electrode is spaced apart from the source and drain electrodes. In the above method, a first channel region is formed between the first gate electrode and the active layer, and wherein a second channel region is formed between the active layer and the second gate electrode.

Another aspect is an organic light emitting display device, comprising: a first substrate; a second substrate disposed to face the first substrate; an organic light emitting device interposed between the first and second substrates, wherein the organic light emitting device comprises i) first and second electrodes, ii) an organic light emitting layer interposed between the first and second electrodes and iii) a thin film transistor configured to control an operation of the organic light emitting device; and wherein the thin film transistor comprises: a substrate; a first gate electrode formed over the substrate; a gate insulating layer formed over the first gate electrode and substrate; an active layer, comprising an oxide semiconductor, formed on the gate insulating layer; a passivation layer formed on the active layer; source and drain electrodes formed on the passivation layer and electrically connected to the active layer; and a second gate electrode formed on the passivation layer and located between the source electrode and the drain electrode.

In the above device, the passivation layer is formed on the active layer, and wherein the source and drain electrodes are electrically connected to the active layer through a contact hole formed on the passivation layer. In the above device, the second gate electrode at least partially overlaps with the first gate electrode. In the above device, the source electrode, the drain electrode, and the second gate electrode are made of the same material, and are formed on the same plane. In the above device, a first channel region is formed between the first gate electrode and the active layer, and wherein a second channel region is formed between the active layer and the second gate electrode.

### BRIEF DESCRIPTION OF THE DRAWINGS

FIG. 1 is a cross-sectional view for describing a thin film transistor according to an embodiment of the present invention.

FIG. 2 is a graph showing a variation (transfer curve) of drain current I_{D} according to gate voltage V_{G}.

FIGS. 3A to 3D are cross-sectional views for describing a method of manufacturing a thin film transistor according to an embodiment of the present invention.

FIGS. 4A and 4B are a plan view and a cross-sectional view for describing one embodiment of an organic light emitting display device having a thin film transistor according to an embodiment of the present invention.

FIG. 5 is a cross-sectional view for describing an organic light emitting device of FIG. 4A.

### DETAILED DESCRIPTION OF CERTAIN INVENTIVE EMBODIMENTS

An active layer of a thin film transistor is generally made of a semiconductor material such as amorphous silicon or poly-silicon. However, when the active layer is made of the amorphous silicon, since mobility is low, it is difficult to implement a driving circuit that operates at high speed. Further, when the active layer is made of the poly-silicon, although the mobility is high, since threshold voltage is non-uniform, an additional compensation circuit needs to be added.

Further, since a method of manufacturing the thin film transistor using low temperature poly-silicon (LTPS) includes a high-price process such as laser processing, etc., it is difficult to control characteristics, and thus the method is difficult to be applied to a large-area substrate.

Japanese Unexamined Patent Publication No. 2004-273614 discloses a thin film transistor using zinc oxide (ZnO) or an oxide semiconductor containing zinc oxide (ZnO) as a principle ingredient as an active layer.

The oxide semiconductor containing zinc oxide (ZnO) as the principle ingredient is evaluated as a stable material while having an amorphous form. When using the oxide semiconductor as the active layer, it is possible to manufacture the thin film transistor at low temperature by using the existing process equipment without additionally purchasing an additional process equipment and an ion injection process is omitted.

However, since the thin film transistor using the oxide semiconductor as the active layer is easily changed in electrical characteristics in accordance with a structure and a process condition, the thin film transistor has low reliability. In particular, current characteristics are deteriorated while static-voltage or static-current driving to vary the threshold voltage, thereby deteriorating the electrical characteristics.

Hereinafter, certain exemplary embodiments of the present invention will be described with reference to the accompanying drawings. Here, when a first element is described as being coupled to a second element, the first element may be not only directly coupled to the second element but may also be indirectly coupled to the second element via a third element. Also, like reference numerals refer to like elements throughout.

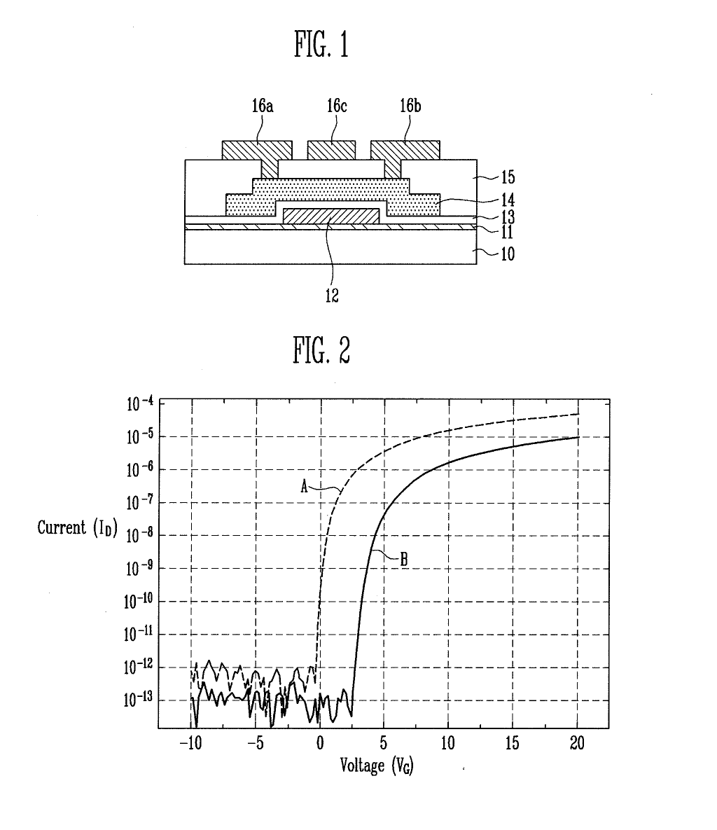

FIG. 1 is a cross-sectional view for describing a thin film transistor according to an embodiment of the present invention.

In one embodiment, as shown in FIG. 1, a buffer layer 11 is formed on a substrate 10 and a first gate electrode 12 is formed on the buffer layer 11. A gate insulating layer 13 may be formed on the first gate electrode 12. An active layer 14, made of, e.g., an oxide semiconductor, may be formed on the gate insulating layer 13. The active layer 14 may include a channel region, a source region, and a drain region. The channel region may at least partially overlap with the first gate electrode 12. Zinc oxide (ZnO) may be used as the oxide semiconductor and at least one ion of gallium (Ga), indium (In), stanium (Sn), zirconium (Zr), hafnium (Hf), and vanadium (V)may be doped on zinc oxide (ZnO).

Further, a passivation layer 15 may be formed on the active layer 14 and the gate insulating layer 13. Source and drain electrodes 16a and 16b, and a second gate electrode 16c may be formed on the passivation layer 15. The source and drain electrodes 16a and 16b may be electrically connected to the source and drain regions of the active layers 14, for example, through a contact hole formed on the passivation layer 15. The second gate electrode 16c may be disposed between the source and drain electrodes 16a and 16b. The source and drain electrodes 16a and 16b may be spaced from the second gate electrode 16c by a predetermined distance. The second gate electrode 16c may partially or wholly overlap with the first gate electrode 12.

The same bias voltage V_{G} or different bias voltages V_{G} may be applied to the first gate electrode 12 and the second gate electrode 16c of the thin film transistor. One embodiment is advantageous compared to a thin film transistor having only one gate electrode, where the bias voltage is applied to the gate electrode, a channel is formed on only one surface of the active layer adjacent to the gate electrode. In one embodiment, since the channels are formed on both surfaces of the active layer 14 adjacent to the first gate electrode 12 and the second gate electrode 16c, current characteristics are improved.

FIG. 2 is a graph showing a variation (transfer curve) of drain current I_{D} according to gate voltage V_{G}. As can be seen from the graph, the thin film transistor (solid line B) according to one embodiment of the present invention has a threshold voltage V_{TH} characteristic more improved than the thin film transistor (dotted line A) which has only one gate electrode.

Further, it is possible to easily control the threshold voltage V_{TH} to a desired level by controlling the magnitude of the bias voltage V_{G} applied to each of the first gate electrode 12 and the second gate electrode 16c.

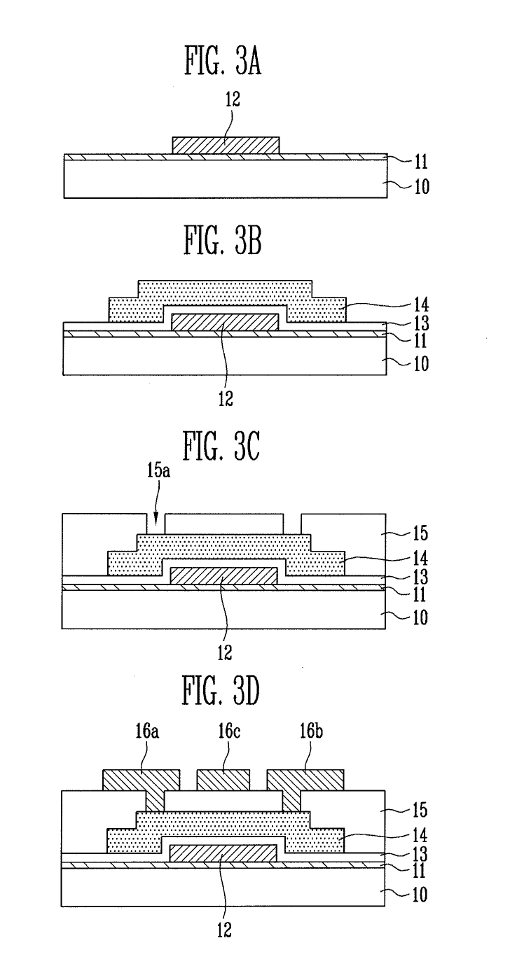

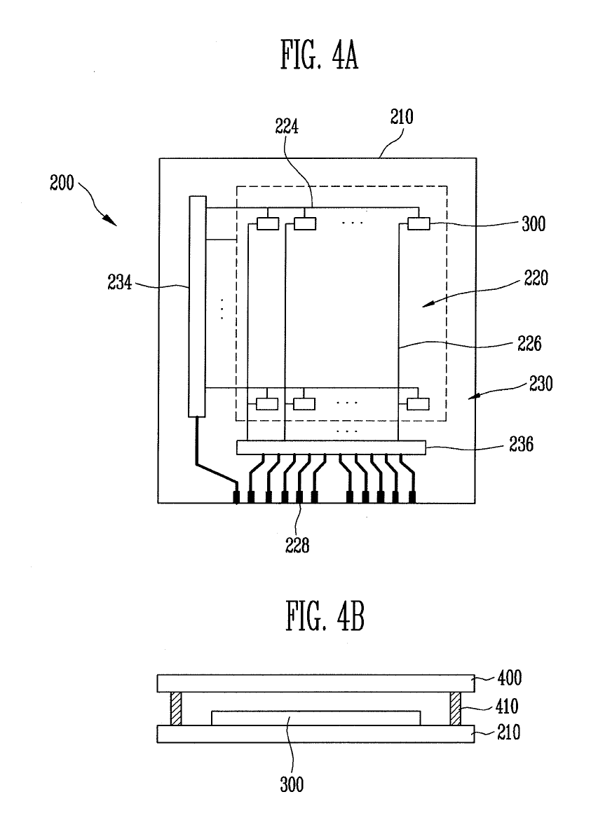

FIGS. 3A to 3D are cross-sectional views for describing a method of manufacturing a thin film transistor according to an embodiment of the present invention.

In one embodiment, as shown in FIG. 3A, a buffer layer 11 is formed on a substrate 10 and a first gate electrode 12 is formed on the buffer layer 11. A semiconductor substrate made of, e.g., silicon (Si), etc., an insulating substrate, made of, e.g., glass, plastic, or the like, or a metallic substrate may be used as the substrate 10. The first gate electrode 12 may be made of metal such as Al, Cr, MoW, or the like.

In one embodiment, as shown in FIG. 3B, a gate insulating layer 13 is formed on the first gate electrode 12 and the buffer layer 11. An active layer 14, including a channel region, a source region, and a drain region may be formed on the gate insulating layer 13, on which an oxide semiconductor is formed through patterning. The channel region may at least partially overlap with the first gate electrode 12 by patterning the active layer 14.

The gate insulating layer 13 may be made of insulating materials, including, but not limited to silicon oxide (SiO), silicon nitride (SiN), etc. An oxide semiconductor layer may be formed by zinc oxide (ZnO) or zinc oxide (ZnO) doped with at least one ion of gallium (Ga), indium (In), stanium (Sn), zirconium (Zr), hafnium (Hf), and vanadium (V), i.e., ZnO, ZnGaO, ZnInO, ZnSnO, GaInZnO, etc.

In one embodiment, as shown in FIG. 3C, a contact hole 15a is formed to expose the source and drain regions of the active layer 14 by forming and patterning a passivation layer 15.

In one embodiment, as shown in FIG. 3D, source and drain electrodes 16a and 16b and a second gate electrode 16c are formed by forming and patterning a conductive layer. In one embodiment, the source and drain electrodes 16a and 16b are electrically connected to the source and drain regions of the active layer 14 through the contact hole 15a. The second gate electrode 16c may be disposed between the source and drain electrodes 16a and 16b. In one embodiment, as shown in FIGS. 1 and 3D, the three electrodes 16a-16c may be formed on the same plane so that they may have substantially the same distance from the substrate 10. The conductive layer, made of, e.g., Mo, MoW, Al, AlNd, AlLiLa, etc., may be formed on the passivation layer 15 so as to bury or fill the contact hole 15a. The source and drain electrodes 16a and 16b may be spaced by a predetermined distance to be electrically separated from the second gate electrode 16c. The second gate electrode 16c may partially or substantially completely overlap with the first gate electrode 12.

In one embodiment, when the passivation layer 15 is used as an etch stop layer while patterning the conductive layer, it is possible to easily perform an etching process and effectively prevent the active layer 14 from being damaged or contaminated.

In one embodiment, the above described thin film transistor can be applied to an organic light emitting display device.

FIGS. 4A and 4B are a plan view and a cross-sectional view for describing one embodiment of an organic light emitting display device having a thin film transistor according to an embodiment of the present invention and focus on and schematically describe a display panel 200 displaying an image.

In one embodiment, as shown in FIG. 4A, a substrate 210 is defined by a pixel region 220 and a non-pixel region 230 in the vicinity of the pixel region 220. A plurality of organic light emitting devices 300, electrically connected between a scan line 224 and a data line 226 in a matrix form, may be formed on the substrate 210 in the pixel region 220. A power supply line (not shown), and a scan driver 234 and a data driver 236, which process a signal provided from the outside through a pad 228 and supply the processed signal to the scan line 224 and the data line 226, may be formed on the substrate 210 in the non-pixel region 230.

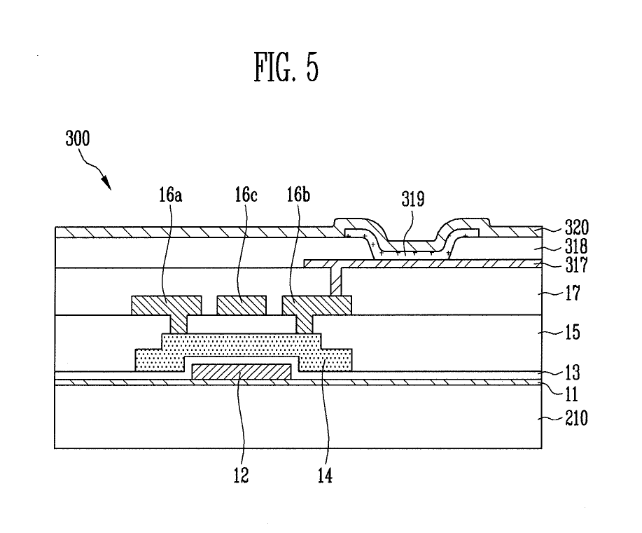

In one embodiment, as shown in FIG. 5, the organic light emitting device 300 includes an anode electrode 317, a cathode electrode 320, and an organic light emitting layer 319 formed between the anode electrode 317 and the cathode electrode 320. The organic light emitting layer 319 may further include a hole injection layer, a hole transport layer, an electron transport layer, and an electron injection layer. Further, the organic light emitting layer 319 may further include a thin film transistor for controlling an operation of the organic light emitting device 300 and a capacitor for maintaining a signal.

The thin film transistor has the same structure shown in FIG. 1 and may be manufactured according to the manufacturing method described with reference to FIGS. 3A to 3D.

Hereinafter, the organic light emitting device 300 including the thin film transistor configured as above will be described in more detail with reference to FIGS. 4A and 5.

The buffer layer 11 may be formed on the substrate 210 and the first gate electrode 12 may be formed on the buffer layer 11 in the pixel region 220. The scan line 224, electrically connected to the first gate electrode 12, may be formed in the pixel region 220. The scan line 224, extending from the scan line 224 of the pixel region 220 and the pad 228 for receiving a signal from the outside, may be formed in the non-pixel region 230.

The formation and/or operation of the elements 12-16c are substantially the same as in the FIG. 1 embodiment. The data line 226, electrically connected to the source and drain electrodes 16a and 16b, may be formed in the pixel region 220 and the data line 226, extending from the data line 226 of the pixel region 220 and the pad 228 for receiving a signal from the outside, may be formed in the non-pixel region 230.

A planarization layer 17 may be formed on i) the source and drain electrodes 16a and 16b, ii) the gate electrode 14a and iii) the passivation layer 15. A via-hole may be formed on the planarization layer 17 to expose the source or drain electrode 16a or 16b. In addition, the anode electrode 317, electrically connected to the source or drain electrode 16a or 16b through the via hole, may be formed.

A pixel definition layer 318 may be formed on the planarization layer 17 and the anode electrode 317 so as to expose a partial region (light emitting region) of the anode electrode 317. The organic light emitting layer 319 may be formed on the exposed portion of the anode electrode 317. The cathode electrode 320 may be formed on the pixel definition layer 318 and the organic light emitting layer 319.

In one embodiment, as shown in FIG. 4B, a sealing substrate 400 for sealing the pixel region 220 is disposed on the top of the substrate 210. The organic light emitting device 300 may be formed and the sealing substrate 400 may be bonded onto the substrate 210 by a sealing material 410 to form the display panel 200.

According to one embodiment, since one gate electrode is formed by the same material on the same plane as the source and drain electrodes, the dual gate structure can easily be implemented without adding an additional mask.

While the present invention has been described in connection with certain exemplary embodiments, it is to be understood that the invention is not limited to the disclosed embodiments, but, on the contrary, is intended to cover various modifications and equivalent arrangements included within the spirit and scope of the appended claims, and-equivalents thereof.

What is claimed is:

1. A thin film transistor, comprising:
a substrate;
a first gate electrode formed over the substrate;
a gate insulating layer formed over the first gate electrode and substrate;
an active layer, comprising an oxide semiconductor, formed on the gate insulating layer;
a passivation layer formed on the active layer;
source and drain electrodes formed on the passivation layer and electrically connected to the active layer; and
a second gate electrode formed on the passivation layer and located between the source electrode and the drain electrode.

2. The thin film transistor of claim 1, wherein the passivation layer is formed on the active layer, and wherein the source and drain electrodes are electrically connected to the active layer through a contact hole formed on the passivation layer.

3. The thin film transistor of claim 1, wherein the second gate electrode at least partially overlaps with the first gate electrode.

4. The thin film transistor of claim 1, wherein the second gate electrode is spaced apart from the source electrode and the drain electrode.

5. The thin film transistor of claim 1, wherein the source electrode, the drain electrode, and the second gate electrode are made of the same material, and are formed on the same plane.

6. The thin film transistor of claim 1, wherein the oxide semiconductor contains zinc oxide (ZnO).

7. The thin film transistor of claim 6, wherein the oxide semiconductor comprises at least one ion of: gallium (Ga), indium (In), stanium (Sn), zirconium (Zr), hafnium (Hf), and vanadium (V).

8. The thin film transistor of claim 1, further comprising:
a buffer layer formed between the substrate and the first gate electrode.

9. A method of manufacturing a thin film transistor, comprising:
forming a first gate electrode over a substrate;
forming a gate insulating layer on the first gate electrode;
forming an semiconductor active layer on the gate insulating layer;
forming a passivation layer on the active layer and gate insulating layer; and
forming source and drain electrodes, and a second gate electrode on the passivation layer, wherein the source and drain electrodes are electrically connected to the active layer, and wherein the second gate electrode is disposed between the source and drain electrodes.

10. The method of manufacturing a thin film transistor of claim 9, wherein forming a passivation layer comprises:
forming the passivation layer on the active layer; and
forming a contact hole on the passivation layer.

11. The method of manufacturing a thin film transistor of claim 10, wherein forming the source electrode, the drain electrode, and the second gate electrode comprises:
forming a conductive layer on the passivation layer so as to fill the contact hole; and
forming i) the source and drain electrodes so as to be electrically connected to the active layer through the contact hole and ii) the second gate electrode between the source and drain electrodes by patterning the conductive layer.

12. The method of manufacturing a thin film transistor of claim 11, further comprising using the passivation layer as an etch stop layer for patterning the conductive layer.

13. The method of manufacturing a thin film transistor of claim 9, wherein the second gate electrode at least partially overlaps with the first gate electrode.

14. The method of manufacturing a thin film transistor of claim 9, wherein the second gate electrode is spaced apart from the source and drain electrodes.

15. The method of manufacturing a thin film transistor of claim 9, wherein a first channel region is formed between the first gate electrode and the active layer, and wherein a second channel region is formed between the active layer and the second gate electrode.

16. An organic light emitting display device, comprising:
a first substrate;
a second substrate disposed to face the first substrate;
an organic light emitting device interposed between the first and second substrates, wherein the organic light emitting device comprises i) first and second electrodes, ii) an organic light emitting layer interposed between the first and second electrodes and iii) a thin film transistor configured to control an operation of the organic light emitting device; and
wherein the thin film transistor comprises
a substrate;
a first gate electrode formed over the substrate;
a gate insulating layer formed over the first gate electrode and substrate;
an active layer, comprising an oxide semiconductor, formed on the gate insulating layer;
a passivation layer formed on the active layer;
source and drain electrodes formed on the passivation layer and electrically connected to the active layer; and
a second gate electrode formed on the passivation layer and located between the source electrode and the drain electrode.

17. The organic light emitting display device of claim 16, wherein the passivation layer is formed on the active layer, and wherein the source and drain electrodes are electrically connected to the active layer through a contact hole formed on the passivation layer.

18. The organic light emitting display device of claim 16, wherein the second gate electrode at least partially overlaps with the first gate electrode.

19. The organic light emitting display device of claim 16, wherein the source electrode, the drain electrode, and the second gate electrode are made of the same material, and are formed on the same plane.

20. The organic light emitting display device of claim 16, wherein a first channel region is formed between the first gate electrode and the active layer, and wherein a second channel region is formed between the active layer and the second gate electrode.
